(19) United States
(12) Patent Application Publication
(10) Pub. No.: US 2026/0063674 A1
(43) Pub. Date: Mar. 5, 2026

(54) Improving Linearity and Mitigating Process Variations for a Radio-frequency Power Detector

(71) Applicant: Apple Inc., Cupertino, CA (US)

(72) Inventor: Kerim Kibaroglu, Tustin, CA (US)

(21) Appl. No.: 18/825,642

(22) Filed: Sep. 5, 2024

(51) Int. Cl. G01R 15/00; G01R 15/16; G01R 21/00; H03F 3/45

(52) U.S. Cl. CPC G01R 15/005; G01R 15/16; G01R 21/00; H03F 3/45475; H03F 2200/141

(57) ABSTRACT

Wireless circuitry is provided that includes a circuit configured to output a radio-frequency signal and a power detector having an input configured to receive the radio-frequency signal. The power detector includes an input transistor and an attenuation circuit coupled to a gate terminal of the input transistor and having series and shunt capacitors of the same capacitor type. The series and shunt capacitors of the same capacitor type can be configured to automatically track process variations of one another for mitigating sensitivity to the process variations. The series and shunt capacitors can have adjustable capacitances that are tuned to adjust a linearity of the power detector.

### FIELD

This disclosure relates generally to electronic devices, including electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through a power amplifier, which is configured to amplify low power analog signals to higher power signals more suitable for transmission through the air over long distances. Radio-frequency signals received at an antenna can be fed through a low noise amplifier, which is configured to amplify low power analog signals to higher power signals for ease of processing at a receiver.

The power level of radio-frequency signals being amplified by such power amplifiers or low noise amplifiers can be measured using power detectors. It can be challenging to design satisfactory power detectors for wireless communications circuitry.

### SUMMARY

An aspect of the disclosure provides circuitry that includes a circuit configured to output a radio-frequency signal and a power detector having an input port configured to receive the radio-frequency signal from the output of the circuit. The power detector includes an input transistor and an attenuation circuit coupled to a gate terminal of the input transistor and having a first capacitor of a given type and a second capacitor of the given type. The first capacitor can have a first terminal coupled to the gate terminal of the input transistor and a second terminal coupled to the input port. The second capacitor can have a first terminal coupled to the gate terminal of the input transistor and a second terminal coupled to a ground power supply line. The first capacitor can have a first adjustable capacitance; the second capacitor can have a second adjustable capacitance; and the first adjustable capacitance and the second adjustable capacitance can be tuned to adjust a linearity of the power detector. The second capacitor can be configured to automatically track process variations of the first capacitor.

An aspect of the disclosure provides a power detection circuit that includes: an input transistor having a first source-drain terminal coupled to an output terminal and having a second source-drain terminal coupled to a power supply line; and an attenuation circuit coupled to a gate terminal of the input transistor and having a first capacitor and a second capacitor configured to track process variations of the first capacitor. The first capacitor can be a series capacitor of a first capacitor type, whereas the second capacitor can be a shunt capacitor of a second capacitor type that is identical to the first capacitor type. The power detection circuit can further include a replica bias transistor having a gate terminal configured to receive a bias voltage, a first load transistor coupled in series with the input transistor, a second load transistor coupled in series with the replica bias transistor, a first resistor coupled between gate and drain terminals of the first load transistor, and a second resistor coupled between gate and drain terminals of the second load transistor. The first and second resistors can have adjustable resistances that are tuned to control a gain of the power detection circuit. The attenuation circuit can be configured to provide an attenuation factor that is tuned to adjust a linearity of the power detection circuit.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having radio-frequency amplifiers in accordance with some embodiments.

FIG. 3 is a diagram showing illustrative power detectors coupled to radio-frequency amplifiers in accordance with some embodiments.

FIG. 4 is a diagram of illustrative transmit or receive control circuitry in accordance with some embodiments.

FIG. 5 is a circuit diagram of an illustrative power detector with an input coupled to series and shunt components configured to mitigate process variations in accordance with some embodiments.

FIG. 6 is a circuit diagram of an illustrative power detector with an input coupled to series and shunt resistive components configured to mitigate process variations in accordance with some embodiments.

FIG. 7 is a diagram plotting third order intercept point as a function of two-tone frequency spacing for various input shunt capacitor values for a power detector in accordance with some embodiments.

### DETAILED DESCRIPTION

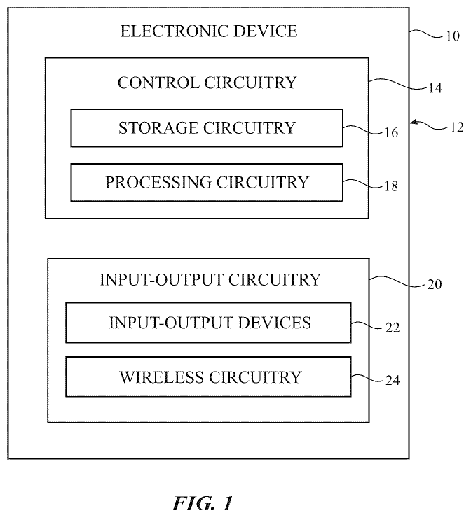

An electronic device such as electronic device 10 of FIG. 1 may be provided with wireless circuitry. Wireless circuitry can include radio-frequency (RF) amplifiers such as power amplifiers and low noise amplifiers. Radio-frequency signals produced by components in the wireless circuitry can be measured using one or more power detectors. A power detector can receive a radio-frequency signal and output a corresponding signal indicative of a power level of the received radio-frequency signal. The power detector can have an input, a shunt element coupled to the input, and a series element coupled to the input. The shunt and series elements can be capacitors of the same type, so that variations in the shunt element can be automatically tracked by those in the series element and vice versa. A power detector configured in this way can be technically advantageous and beneficial by reducing sensitivity to process variations and thus improving detection accuracy, by improving gain control at the input of the power detector, by improving linearity based on an attenuation factor associated with the series and shunt elements, and thus improving the overall signal-to-distortion ratio (SDR) and reducing the power consumption of the power detector.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-300 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

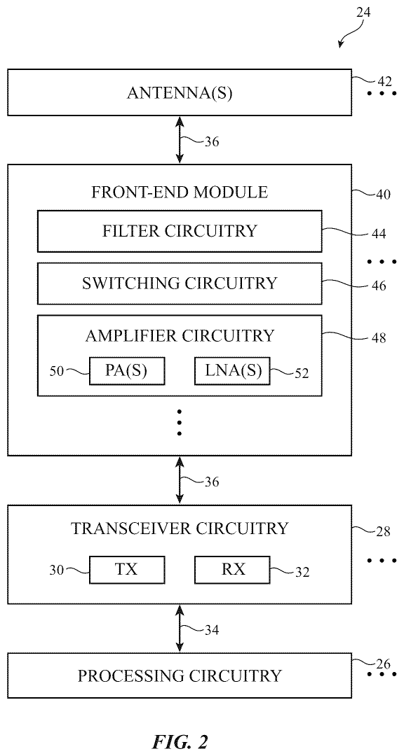

FIG. 2 is a diagram showing illustrative components within wireless circuitry 24 that can include one or more power detectors. As shown in FIG. 2, wireless circuitry 24 may include processing circuitry such as processing circuitry 26, radio-frequency (RF) transceiver circuitry such as radio-frequency transceiver 28, radio-frequency front-end circuitry such as radio-frequency front-end module (FEM) 40, and antenna(s) 42. Processing circuitry 26 may include a baseband processor, application processor, general purpose processor, microprocessor, microcontroller, digital signal processor, host processor, application specific signal processing hardware, or other type of processor. Processing circuitry 26 may be coupled to transceiver 28 over path 34. Transceiver 28 may be coupled to antenna 42 via radio-frequency transmission line path 36. Radio-frequency front-end module 40 may be disposed on radio-frequency transmission line path 36 between transceiver 28 and antenna 42.

In the example of FIG. 2, wireless circuitry 24 is illustrated as including only a single processing unit 26, a single transceiver 28, a single front-end module 40, and a single antenna 42 for the sake of clarity. In general, wireless circuitry 24 may include any desired number of processing units 26, any desired number of transceivers 28, any desired number of front-end modules 40, and any desired number of antennas 42. Each processing unit 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front-end module 40 disposed thereon. If desired, two or more front-end modules 40 may be disposed on the same radio-frequency transmission line path 36. If desired, one or more of the radio-frequency transmission line paths 36 in wireless circuitry 24 may be implemented without any front-end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processing circuitry 26 may provide transmit signals (e.g., digital or baseband signals) to transceiver 28 over path 34. Transceiver 28 may further include circuitry for converting the transmit (baseband) signals received from processing circuitry 26 configured to generate a current that at least partially cancels a non-linear current associated with the input transistor into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processing circuitry 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front-end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front-end module 40. Transceiver 28 may include circuitry such as receiver (RX) 32 for receiving signals from front-end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processing circuitry 26 over path 34.

Front-end module (FEM) 40 may include radio-frequency front-end circuitry that operates on the radio-frequency signals conveyed (transmitted and/or received) over radio-frequency transmission line path 36. FEM 40 may, for example, include front-end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), signal attenuators, impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front-end module components may be mounted to a common (shared) substrate such as a rigid printed circuit board substrate or flexible printed circuit substrate. If desired, the various front-end module components may also be integrated into a single integrated circuit chip. If desired, amplifier circuitry 48 and/or other components in front-end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front-end module 40. For example, transceiver 28 may be formed on another substrate such as the main logic board of device 10, a rigid printed circuit board, or flexible printed circuit that is not a part of front-end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processing circuitry 26 and/or portions of transceiver 28 (e.g., a host processor on transceiver 28) may form a part of control circuitry 14. Control circuitry 14 (e.g., portions of control circuitry 14 formed on processing circuitry 26, portions of control circuitry 14 formed on transceiver 28, and/or portions of control circuitry 14 that are separate from wireless circuitry 24) may provide control signals (e.g., over one or more control paths in device 10) that control the operation of front-end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), cellular sidebands, 6G bands between 100-1000 GHz (e.g., sub-THz, THz, or THF bands), etc.), other centimeter or millimeter wave frequency bands between 10-300 GHz (e.g., a short range wireless data transfer band that supports in-band full duplex communications such as a band between around 57 GHz and 64 GHz), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, radio transceiver circuitry that handles unlicensed radio bands reserved for industrial, scientific, and medical (ISM) purposes, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

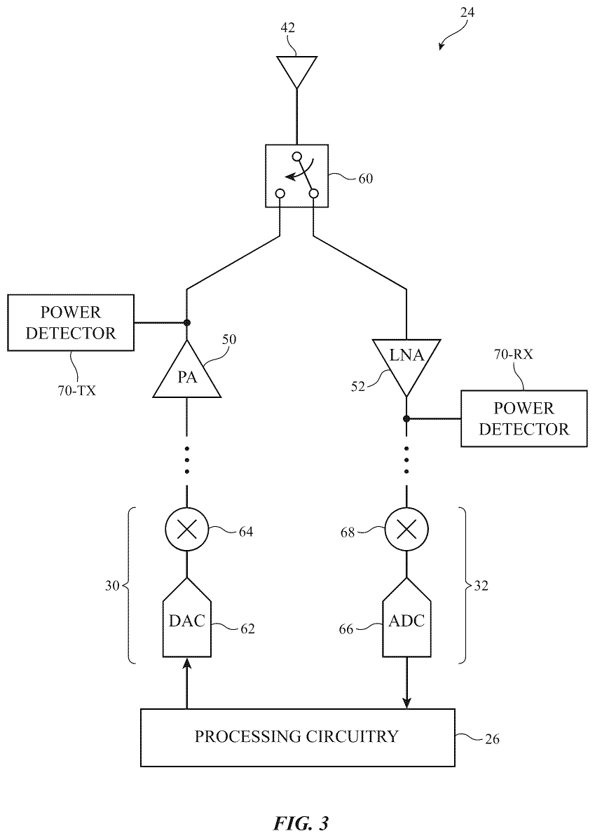

Radio-frequency amplifiers may be coupled to power detectors for power monitoring purposes. FIG. 3 is a diagram showing illustrative power detectors coupled to radio-frequency amplifiers. As shown in FIG. 3, wireless circuitry 24 can have one or more antenna 42 that is coupled to a transmit path and a receive path via a radio-frequency duplexing circuit such as duplexer 60. Duplexer 60 may have a first port coupled to a shared antenna 42, a second port coupled to the transmit path (e.g., a second port configured to receive amplified radio-frequency signals to be radiated by antenna 42), and a third port coupled to the receive path (e.g., a third port to which radio-frequency signals received by antenna 42 are conveyed). This example in which the transmit path and the receive path are coupled to a shared antenna via a duplexer 60 is illustrative. In other embodiments, the transmit path and the receive path can be coupled to separate antennas.

The receive path can include low noise amplifier (LNA) circuitry 52, a downconverting mixing circuit such as mixer 68, and a data converter such as analog-to-digital converter (ADC) 66. The LNA circuitry 52 can include one or more amplifiers coupled in series and/or in parallel. Mixer 68 may use a local oscillator signal to downconvert (or demodulate) the radio-frequency signals to baseband (or intermediate) frequencies. Analog-to-digital converter (ADC) circuit 66 can then convert the demodulated signals from the analog domain to the digital domain to generate corresponding digital baseband signals. Mixer 68 and ADC circuit 66 are sometimes be considered part of receiver (RX) circuitry 32. The digital baseband signals can then be received by processing circuitry 26. Processing circuitry 26 may represent one or more processors such as a baseband processor, an application processor, a digital signal processor, a microcontroller, a microprocessor, a central processing unit (CPU), a programmable device, a combination of these circuits, circuitry 26 described in connection with FIG. 2, and/or one or more processors within circuitry 18 of FIG. 1.

The circuitry described above for processing signals received by antenna 42 is sometimes referred to collectively as wireless “receiving” circuitry. If desired, one or more additional front-end module components such as radio-frequency filter circuitry 44 of FIG. 2 (e.g., low pass filters, high pass filters, notch filters, band pass filters, attenuators, multiplexing circuitry, duplexer circuitry, diplexer circuitry, triplexer circuitry, etc.), switching circuitry 46 (e.g., one or more radio-frequency switches), impedance matching circuitry, antenna tuning circuitry (e.g., networks of capacitors, resistors, inductors, and/or switches that adjust the frequency response of antenna 42), radio-frequency coupler circuitry, charge pump circuitry, power management circuitry, and/or any other desired front-end module circuitry can optionally be coupled at the input and/or output of LNA circuitry 52 along the radio-frequency receive path.

On the other hand, the transmit path can include power amplifier (PA) circuitry 50, a upconverting mixing circuit such as mixer 64, and a data converter such as digital-to-analog converter (DAC) 62. Processing circuitry 26 can generate digital baseband signals, sometimes referred to as digital signals for transmission. DAC circuit 62 can convert the digital baseband signals from the digital domain to the analog domain to generate corresponding analog baseband signals. Mixer 64 may use a local oscillator signal to upconvert (or modulate) the radio-frequency signals to radio (or intermediate) frequencies. DAC circuit 62 and mixer 64 are sometimes be considered part of transmitter (TX) circuitry 30. The upconverted radio-frequency signals can then be fed to amplifier circuitry 50. The power amplifier circuitry 52 can include one or more amplifiers coupled in series and/or in parallel that are configured to amplify signals for transmission by antenna 42.

The circuitry described above for preparing signals for transmission by antenna 42 is sometimes referred to collectively as wireless “transmitting” circuitry. If desired, one or more additional front-end module components such as radio-frequency filter circuitry 44 of FIG. 2 (e.g., low pass filters, high pass filters, notch filters, band pass filters, attenuators, multiplexing circuitry, duplexer circuitry, diplexer circuitry, triplexer circuitry, etc.), switching circuitry 46 (e.g., one or more radio-frequency switches), impedance matching circuitry, antenna tuning circuitry (e.g., networks of capacitors, resistors, inductors, and/or switches that adjust the frequency response of antenna 42), radio-frequency coupler circuitry, charge pump circuitry, power management circuitry, and/or any other desired front-end module circuitry can optionally be coupled at the input and/or output of amplifier circuitry 50 along the radio-frequency transmit path.

Power detection circuits can be coupled to the outputs of the radio-frequency amplifiers to enable power monitoring operations. Still referring to FIG. 3, a first power detection circuit such as power detector 70-TX may be coupled to the output of transmitting amplifier circuitry 50, whereas a second power detection circuit such as power detector 70-RX may be coupled to the output of receiving amplifier circuitry 52. Power detector 70-TX can be used to detect or measure an output power level of radio-frequency signals generated at the output of amplifier circuitry 50. The detected output power level can, for example, be used by an automatic power control (APC) algorithm to dynamically adjust the gain of power amplifier circuitry 50 to ensure that the transmit path is outputting signals at desired power levels. The APC algorithm, which can run on processing circuitry 26 or other control circuitry in device 10, can compare the measured output power level to a reference power level. If the output power level is too high, the APC algorithm can reduce the gain of amplifier 50. If the output power level is too low, the APC algorithm can increase the gain of amplifier 50.

Power detector 70-RX can be used to detect or measure an output power level of radio-frequency signals generated at the output of receiving amplifier circuitry 52. The detected output power level can then be used by an automatic gain control (AGC) algorithm to dynamically adjust the gain of LNA circuitry 52 to ensure that the receive path is outputting signals at desired power levels regardless of the strength of signals arriving at the input of circuitry 52. The AGC algorithm, which can run on processing circuitry 26 or other control circuitry in device 10, can be used to ensure that signals are output from circuitry 52 at a constant output power level. If the input signal is weak, the AGC algorithm can increase the gain of amplifier 52 to maintain a constant output level. If the input signal is strong, then the AGC algorithm can reduce the gain of amplifier 52 to prevent the output level from becoming too high.

The example of FIG. 3 in which power detectors 70-TX and 70-RX are coupled at the radio-frequency amplifier outputs is illustrative. If desired, one or more power detectors can be coupled at the output of DAC 62, at the output of mixer 64, and/or at any other point(s) along the transmit path, at the output of mixer 68, at the output of ADC 66, and/or at any other point(s) along the receive path.

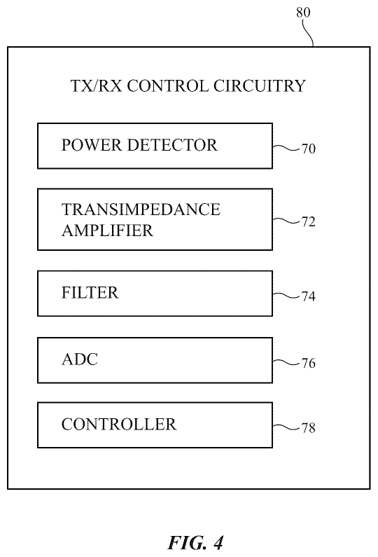

A power detector 70 is sometimes considered part of transmit (TX) or receive (RX) control circuitry 80 (see, e.g., FIG. 4). Transmit control circuitry 80 can include a transmit power detector 70 (see, e.g., power detector 70-TX coupled to the output of power amplifier 50 in FIG. 3 or to any other node along the transmit path), whereas receive control circuitry 80 can include a receive power detector 70 (see, e.g., power detector 70-RX coupled to the output of LNA 52 in FIG. 3 or to any other node along the receive path). As shown in FIG. 4, TX/RX control circuitry 80 can further include an amplifier such as a transimpedance amplifier 72, a filtering circuit such as filter 74, a data converter such as analog-to-digital converter (ADC) 76, and an associated controller 78.

Power detector 70 can have an output that is coupled to transimpedance amplifier 72 (e.g., transimpedance amplifier 72 can have an input configured to receive signals from power detector 70). Transimpedance amplifier 72 can refer to and be defined herein as a circuit that is configured to convert an input current signal to a corresponding output voltage signal. Transimpedance amplifier 72 may have an output that is coupled to filter 74 (e.g., filter 74 can have an input configured to receive signals from amplifier 72). Filter 74 can be an antialiasing filter (as an example). Filter 74 may have an output that is coupled to ADC circuit 76 (e.g., ADC 76 can have an input configured to receive signals from filter 74). ADC circuit 76 can output corresponding digital signals to controller 78. Controller 78 within TX control circuitry 80 may be used to run or execute an APC algorithm for controlling power amplifier circuitry 50, whereas controller 78 within RX control circuitry 80 may be used to run or execute or an AGC algorithm for controlling receive LNA circuitry 52. In general, controller 78 may be formed as part of processing circuitry 26 (see FIGS. 2 and 3), processing circuitry 18 (see FIG. 1), or other processing subsystem on device 10. The example sometimes described herein in which power detector 70 has an output coupled to transimpedance amplifier 72 is illustrative. In general, the output of power detector 70 can be coupled to other types of downstream processing circuitry or control circuitry.

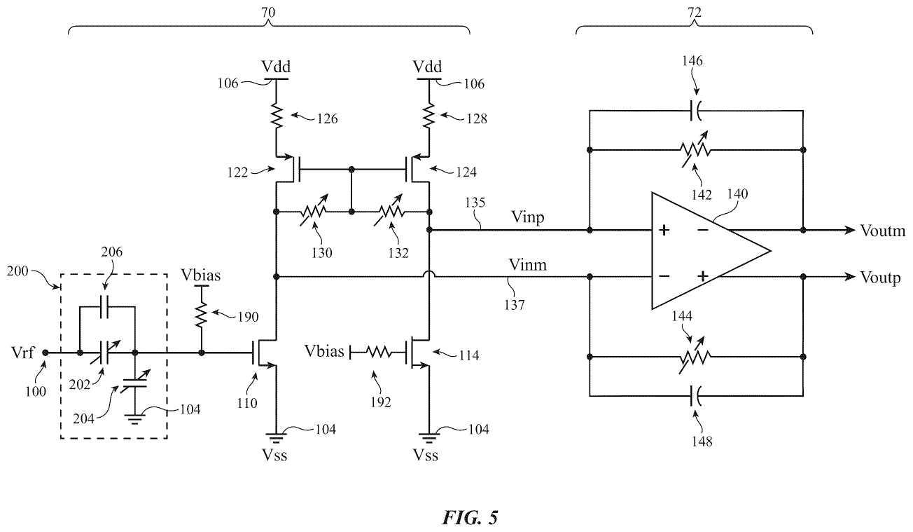

FIG. 5 is a circuit diagram of an illustrative power detection circuit 70 with a single-ended input. As shown in FIG. 5, power detection circuit 70 may include an input transistor 110, a bias transistor 114, a first load transistor 122, and a second load transistor 124. Transistors 110 and 114 can be n-type (e.g., n-channel) metal-oxide-semiconductor (NMOS) transistors, whereas load transistors 122 and 124 can be p-type (e.g., p-channel) metal-oxide-semiconductor (PMOS) transistors. Input transistor 110 may have a gate terminal coupled to an input port 100, a source terminal coupled to a ground line 104 (e.g., a ground power supply terminal on which ground power supply voltage Vss is provided), and a drain terminal coupled to a first power detector output path 137 on which voltage Vinm is provided. The terms “source” and “drain” are sometimes used interchangeably when referring to current-conducting terminals of a metal-oxide-semiconductor transistor. The source and drain terminals are therefore sometimes referred to as “source-drain” terminals (e.g., a transistor has a gate terminal, a first source-drain terminal, and a second source-drain terminal).

If desired, a cascode transistor may be coupled between the drain terminal of input transistor 110 and the first output path 137. Input port 100 may be coupled to an output of a radio-frequency amplifier, mixer, or data converter (e.g., power detector input port 100 may be configured to receive a radio-frequency signal from an associated wireless circuit). The signal received at input port 100 may be a radio-frequency signal Vrf or other AC signal.

Bias transistor 114 may have a source terminal coupled to the ground line 104, a gate terminal configured to receive bias voltage Vbias via a series resistor 192, and a drain terminal coupled to a second power detector output path 135 on which voltage Vinp is provided. Resistor 192 is optional. If desired, a cascode transistor may be coupled between the drain terminal of bias transistor 114 and the second output path 135. Bias transistor 114 can be sized equally to input transistor 110 and can sometimes be referred to and defined herein as a “replica bias transistor.” Configured in this way, transistors 110 and 114 may be operated to perform an AC voltage to DC current conversion and is sometimes referred to as an AC-to-DC converter or a “squarer” circuit. A squarer circuit can refer to and be defined herein as a subcircuit configured to perform a squaring function x² for an input signal x received at input port 100.

Load transistor 122 may be coupled in series with input transistor 110. Load transistor 122 may have a drain terminal coupled to output path 137, a gate terminal that is coupled to its own drain terminal via resistor 130, and a source terminal coupled to positive power supply line 106 (e.g., a positive power supply terminal on which positive supply voltage Vdd is provided) via source degeneration resistor 126. Similarly, load transistor 124 may be coupled in series with replica bias transistor 114. In particular, load transistor 124 may have a drain terminal coupled to output path 135, a gate terminal that is coupled to its own drain terminal via resistor 132, and a source terminal coupled to power supply line 106 via source degeneration resistor 128. Source degeneration resistors 126 and 128 are optional. Resistors 130 and 132 can optionally be adjustable resistors that are tuned using controller 78 of FIG. 4 or other control circuitry within device 10 (FIG. 1). Resistors 130 and 132 can have resistances that are adjusted to tune a gain of power detector 70. The resistance of resistors 130 and 132 can provide an extra control knob for increasing the dynamic range of power detector 70. Output paths 135 and 137 may collectively serve as a differential output for power detector 70. The node disposed between transistors 110 and 122 and coupled to output path 137 can be referred to as a first output terminal of power detector 70, whereas the node disposed between transistors 114 and 124 and coupled to output path 135 can be referred to as a second output terminal of power detector 70, or vice versa.

The first output terminal and the second output terminal of power detector 70 can collectively serve as a power detector differential output port. The output port of power detector 70 can be coupled to inputs of transimpedance amplifier 72 (e.g., a differential amplifier). In the example of FIG. 5, the first power detector output terminal is coupled to a first (negative) input of amplifier 72 via path 137, whereas the second power detector output terminal is coupled to a second (positive) input of amplifier 72 via path 135.

Transimpedance amplifier 72 can further include a first (+) output terminal on which output voltage Voutp is produced, a second (−) output terminal on which output voltage Voutm is produced, feedback resistor 142 and capacitor 146 coupled between the second input and the second output terminals of amplifier 72, and feedback resistor 144 and capacitor 148 coupled between the first input and the first output terminals of amplifier 72. Capacitors 146 and 148 are optional and can be omitted, if desired. The circuit structure of transimpedance amplifier 72 as shown in FIG. 5 is exemplary. Other types of transimpedance amplifiers can be employed. The output of amplifier 72 can optionally be coupled to one or more filters, to one or more ADCs 76, and/or to one or more controller 78 as described in connection with FIG. 4. The use of transimpedance amplifier 72 at the output of power detector 70 can be technically advantageous and beneficial by providing the overall power detection circuitry with better sensitivity (e.g., to detect smaller signals), a more linear power detector response, and reduced modulation error. Amplifier 72 is sometimes referred to as a power detector output stage. The use of transimpedance amplifier 72 at the output of power detector 70 is optional. If transimpedance amplifier 72 is coupled at the output of power detector 70, then resistors 130 and 132 can be fixed resistors (e.g., resistor with fixed resistances) since amplifier 72 presents a low impedance at the output port of power detector 70. In such an arrangement, the feedback resistors 142 and 144 of amplifier 72 can be adjustable resistors that are tuned using controller 78 of FIG. 4 or other control circuitry with device 10 (see FIG. 1) for tuning the gain of power detector 70.

The gate terminal of input transistor 110 can be configured to receive bias voltage Vbias via a bias resistor 190. The gate terminal of input transistor 110 is further coupled to a series component such as a series capacitor 206. Series capacitor 206 can have a first terminal coupled to the gate terminal of input transistor 110 and a second terminal coupled to power detector input port 100. Series capacitor 206 can serve as an AC (alternating current) coupling component for conveying high(er) frequency (AC) signals from port 100 to the gate terminal of input transistor 110 while blocking low(er) frequency DC (direct current) signals.

A power detector having only a series capacitor at its input forms a capacitive divider with the input transistor (i.e., forming a capacitive divider with the parasitic gate capacitance of the input transistor). This capacitive divider produces a division ratio that fluctuates as a function of process variation. Since the process variation associated with the series capacitor and the input MOS transistor can fluctuate independently of each other, the division ratio of the resulting power detector can be unpredictable. Conventional power detector designs set the series capacitor and input transistor sizing to meet gain, noise, linearity, power, variation, and other design criteria that impact the detection accuracy and dynamic range at the system level. Such configurations, however, impose a tradeoff between process variation and linearity on the power detector. For instance, a smaller series capacitor results in improved linearity at the input side but introduces greater process variation since capacitor variation is typically greater than MOS transistor process variation.

In accordance with an embodiment, power detector 70 can be provided with one or more additional component(s) at the power detector input port that breaks the design tradeoff imposed by conventional power detector designs. As shown in FIG. 5, power detector 70 can further include a series component 202 and a shunt component 204 coupled to the power detector input port 100. Series component 202 can be a series capacitor having a first terminal coupled to the gate terminal of input transistor 110 and a second terminal coupled to input port 100. Series capacitor 202 can be an adjustable capacitor implemented as a bank of switchable capacitors (e.g., an array of capacitors each of which is selectively activated by a respective switch), a variable capacitor sometimes referred to as a varactor, a varicap diode, a metal-oxide-semiconductor capacitor (MOSCAP), and/or other components configured to provide a variable capacitance. Adjustable series capacitor 202 can be coupled in parallel with AC coupling capacitor 206. AC coupling capacitor 206 may have a fixed capacitance (e.g., capacitor 206 may be a non-adjustable capacitor). Adjustable series capacitor 202 can obviate the need of a separate AC coupling capacitor 206. If fixed AC coupling capacitor 206 were to be omitted, adjustable series capacitor 202 can serve as an AC coupling component.

Shunt component 204 can be a shunt capacitor having a first terminal coupled to the gate terminal of input transistor 110 and a second terminal coupled to ground line 104. The term “shunt” can refer to and be defined herein as having one terminal coupled to a power supply line such as ground line 104. Shunt capacitor 204 can be an adjustable capacitor implemented as a bank of switchable capacitors (e.g., an array of capacitors each of which is selectively activated by a respective switch), a variable capacitor sometimes referred to as a varactor, a varicap diode, a metal-oxide-semiconductor capacitor (MOSCAP), and/or other components configured to provide a variable capacitance. Capacitors 202 and 204 can be tuned using controller 78 of FIG. 4 or other control circuitry within device 10 (FIG. 1)

In particular, shunt capacitor 204 and series capacitor 202 should be implemented as the same type of capacitors. As an example, series capacitor 202 and shunt capacitor 204 can both be implemented as metal-on-metal (MOM) capacitors. As another example, series capacitor 202 and shunt capacitor 204 can both be implemented as metal-insulator-metal (MIM) capacitors. As another example, series capacitor 202 and shunt capacitor 204 can both be implemented as metal-oxide-semiconductor (MOS) capacitors (e.g., both n-type MOS capacitors or both p-type MOS capacitors). As another example, series capacitor 202 and shunt capacitor 204 can both be implemented as polysilicon-insulator-polysilicon (PIP) capacitors. As another example, series capacitor 202 and shunt capacitor 204 can both be implemented as trench capacitors (e.g., capacitor formed by filling a trench with conductive and high-k dielectric material). Implementing capacitors 202 and 204 using the same capacitor type can help ensure that any process variation associated with one capacitor is automatically tracked by the other capacitor of the same type. Such configuration is technically advantageous and beneficial to mitigate any process variation associated with capacitors 202 and 204, thus improving detection accuracy. In contrast, two capacitors of different capacitor types do not necessarily track the process variations of one another. For instance, a MOM capacitor may not track the process variations of a MIM capacitor.

Series capacitor 202 and shunt capacitor 204 can form part of a signal attenuation circuit 200 at the input of power detector 70. Capacitors 202 and 204 can be separately or jointly adjusted to tune an attenuation (or gain) factor of attenuation circuit 200. Attenuator 200 can reduce the signal swings at the input of power detector 70, which can improve the overall linearity of power detector 70. In other words, the use of attenuator 200 to provide a tunable attenuation factor can help improve gain control at the input of the power detector and thus improve the overall signal-to-distortion ratio (SDR) and reduce the power consumption of power detector 70. The AC coupling capacitor 206, if present, can also be considered part of attenuator 200.

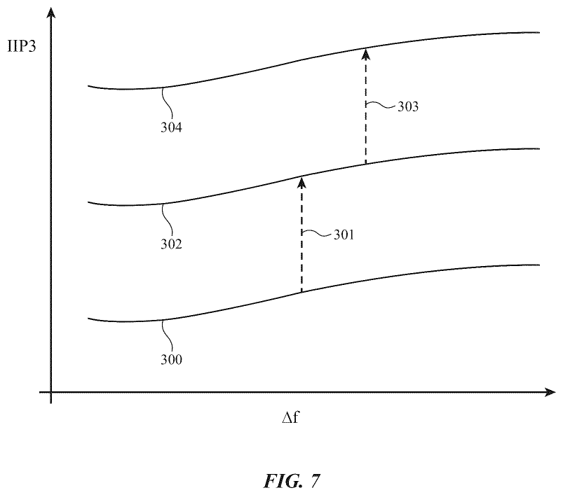

The linearity of power detector 70 can be a function of the attenuation factor provided by attenuator 200. FIG. 7 is a diagram plotting third order intercept point as a function of two-tone frequency spacing for various input capacitor values for power detector 70 in accordance with some embodiments. In particular, FIG. 7 plots the “input” third-order intercept point or IIP3, which is a parameter used to characterize the linearity of an electronic circuit such as power detector 70. The input 3^{rd} order intercept point can represent the input power level Pin at which the third-order intermodulation products generated by power detector 70 reach the same level as the desired output signal in a two-tone scenario. In general, it is desirable to increase the IIP3. Intermodulation distortion arises when at least two signals at different frequencies are applied to a non-linear circuit and when the amplitude modulation or mixing (multiplication) of the two signals when their sum is raised to a power greater than one generates intermodulation products that are not just at harmonic frequencies (integer multiples) of either input signal but also at the sum and differences of the input signal frequencies and also at sums and differences of multiples of those frequencies. The x-axis of FIG. 7 represents a frequency difference or delta separating the two tones generating the intermodulation products.

As shown in FIG. 7, curve 300 represents the IIP3 profile for a power detector that has only a series (AC coupling) capacitor without any associated shunt capacitor 204 (i.e., if shunt capacitor 204 were to be omitted, disabled, or switched out of use). Curve 302 represents the IIP3 profile for power detector 70 that includes series capacitor 202 and an associated shunt capacitor 204 configured with a relatively small capacitance value. Reducing the capacitance of shunt capacitor 204, relative to the capacitance of series capacitor 202, can increase the magnitude of the attenuation factor (i.e., to reduce the amount of signal attenuation). Here, curve 302 shows improved IIP3 values relative to curve 300, as indicated by arrow 301. Furthermore, curve 304 represents the IIP3 profile for power detector 70 that includes series capacitor 202 and an associated shunt capacitor 204 configured with a relatively large capacitance value. Increasing the capacitance of shunt capacitor 204, relative to the capacitance of series capacitor 202, can decrease the magnitude of the attenuation factor (i.e., increasing the amount of signal attenuation). Here, curve 304 shows further improved IIP3 values relative to curve 302, as indicated by arrow 303. This further illustrates how the linearity of power detector 70 can be adjusted based on the attenuation factor of attenuation circuit 200.

The embodiment of FIG. 5 in which power detector 70 has a single-ended input port is exemplary. The techniques described herein can be adapted to a power detector with a differential input port. For example, a power detector with a differential input port can include at least first and second input transistor, a first series capacitor coupled to a gate terminal of the first input transistor, a first shunt capacitor coupled to the gate terminal of the first input transistor, a second series capacitor coupled to a gate terminal of the second input transistor, and a second shunt capacitor coupled to the gate terminal of the second input transistor. The first series capacitor, the first shunt capacitor, the second series capacitor, and the second shunt capacitor can all be adjustable capacitors of the same type. A power detector configured in this way can be technically advantageous and beneficial by reducing sensitivity to process variations and thus improving detection accuracy, by improving gain control at the input of the power detector, by improving linearity based on an attenuation factor associated with the series and shunt components, and thus improving the overall signal-to-distortion ratio (SDR) and reducing the power consumption of the power detector.

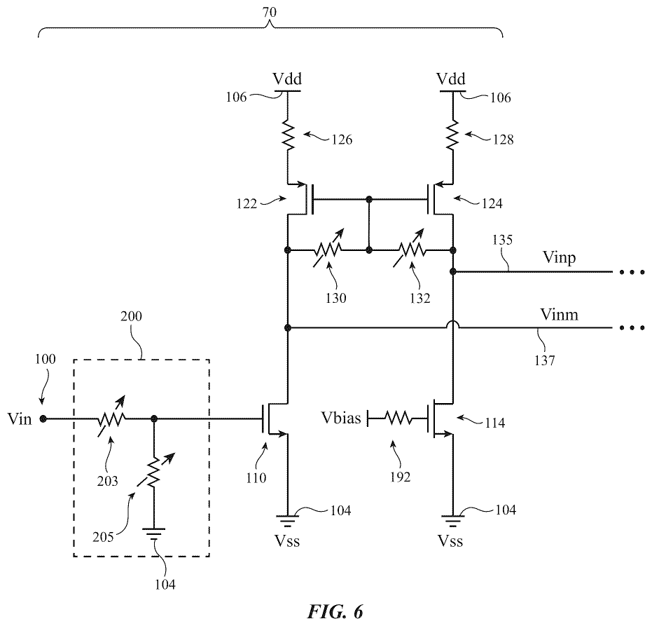

The embodiment of FIG. 5 in which power detector 70 has an attenuation circuit 200 formed using capacitive components 202 and 204 is illustrative. FIG. 6 illustrates another embodiment of power detector 70 having an attenuation circuit 200 formed using resistive components 203 and 205. A resistor-based attenuation circuit 200 can be employed at the input of power detector 70 for low(er) frequency applications (e.g., for applications where power detector is configured to receive non-radio-frequency signals). Series component 203 can be a series resistor having a first terminal coupled to the gate terminal of input transistor 110 and a second terminal coupled to input port 100. Series resistor 203 can be an adjustable resistor implemented as a bank of switchable resistors (e.g., an array of resistors each of which is selectively activated by a respective switch), one or more transistors having gate terminals configured to receive an analog control voltage, a resistive ladder, a variable resistor (e.g., a digitally controlled resistor), one or more transistors coupled together in parallel and/or in series, and/or other components configured to provide a variable resistance.

Shunt component 205 can be a shunt resistor having a first terminal coupled to the gate terminal of input transistor 110 and a second terminal coupled to ground line 104. Shunt resistor 205 can be implemented as a bank of switchable resistors (e.g., an array of resistors each of which is selectively activated by a respective switch), one or more transistors having gate terminals configured to receive an analog control voltage, a resistive ladder, a variable resistor (e.g., a digitally controlled resistor), one or more transistors coupled together in parallel and/or in series, and/or other components configured to provide a variable resistance.

In particular, shunt resistor 205 and series resistor 203 should be implemented as the same type of resistors. As an example, series resistor 203 and shunt resistor 205 can both be implemented as polysilicon resistors (e.g., resistors formed from a layer of polysilicon deposited on a semiconductor substrate). As another example, series resistor 203 and shunt resistor 205 can both be implemented as metal resistors (e.g., a resistor formed from metal routing paths in an interconnect stack). As another example, series resistor 203 and shunt resistor 205 can both be implemented as diffused resistors (e.g., resistors formed by diffusing/doping impurities into a semiconductor substrate). As another example, series resistor 203 and shunt resistor 205 can both be implemented as thin-film resistors (e.g., resistors formed from a thin film of resistive material over a semiconductor substrate).

Implementing resistors 203 and 205 using the same resistor type can help ensure that any process variation associated with one resistor is automatically tracked by the other resistor of the same type. A power detector configured in this way can be technically advantageous and beneficial by reducing sensitivity to process variations and thus improving detection accuracy, by improving gain control at the input of the power detector, by improving linearity based on an attenuation factor associated with the series and shunt components, and thus improving the overall signal-to-distortion ratio (SDR) and reducing the power consumption of the power detector.

The methods and operations described above in connection with FIGS. 1-7 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, processing circuitry 26 of FIGS. 2 and 3, controller 78 of FIG. 4, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users,

What is claimed is:

1. Circuitry comprising:
a circuit configured to output a radio-frequency signal; and
a power detector having an input port configured to receive the radio-frequency signal from the output of the circuit, wherein the power detector comprises:
an input transistor; and
an attenuation circuit coupled to a gate terminal of the input transistor and having a first capacitor of a given type and a second capacitor of the given type.

2. The circuitry of claim 1, wherein the first capacitor comprises a first terminal coupled to the gate terminal of the input transistor and a second terminal coupled to the input port.

3. The circuitry of claim 2, wherein the second capacitor comprises a first terminal coupled to the gate terminal of the input transistor and a second terminal coupled to a ground power supply line.

4. The circuitry of claim 3, wherein:
the first capacitor has a first adjustable capacitance;
the second capacitor has a second adjustable capacitance; and
the first adjustable capacitance and the second adjustable capacitance are tuned to adjust a linearity of the power detector.

5. The circuitry of claim 3, wherein the power detector further comprises a non-adjustable alternating current (AC) coupling capacitor having a first terminal coupled to the gate terminal of the input transistor and a second terminal coupled to the input port.

6. The circuitry of claim 3, wherein the power detector further comprises a bias resistor having a first terminal coupled to the gate terminal of the input transistor and a second terminal configured to receive a bias voltage.

7. The circuitry of claim 1, wherein the second capacitor of the given type is configured to automatically track process variations of the first capacitor of the given type.

8. The circuitry of claim 1, wherein the power detector further comprises:
a replica bias transistor having a gate terminal configured to receive a bias voltage;
a first load transistor coupled in series with the input transistor;
a second load transistor coupled in series with the replica bias transistor;
a first resistor coupled between gate and drain terminals of the first load transistor; and
a second resistor coupled between gate and drain terminals of the second load transistor.

9. The circuitry of claim 8, wherein the first resistor and the second resistor have adjustable resistances that are tuned to control a gain of the power detector.

10. The circuitry of claim 8, further comprising:
a transimpedance amplifier having a first input terminal coupled to a first node disposed between the input transistor and the first load transistor, a second input terminal coupled to a second node disposed between the replica bias transistor and the second load transistor, a first feedback resistor coupled to the first input terminal, and a second feedback resistor coupled to the second input terminal, wherein the first and second feedback resistors have adjustable resistances that are tuned to control a gain of the power detector.

11. A power detection circuit comprising:
an input transistor having a first source-drain terminal coupled to an output terminal and having a second source-drain terminal coupled to a power supply line; and
an attenuation circuit coupled to a gate terminal of the input transistor and having a first capacitor and a second capacitor configured to track process variations of the first capacitor.

12. The power detection circuit of claim 11, wherein:
the first capacitor comprises a first terminal coupled to the gate terminal of the input transistor and a second terminal configured to receive a radio-frequency signal; and
the second capacitor comprises a first terminal coupled to the gate terminal of the input transistor and a second terminal coupled to the power supply line.

13. The power detection circuit of claim 12, wherein the first capacitor comprises a series capacitor of a first capacitor type, and wherein the second capacitor comprises a shunt capacitor of a second capacitor type that is identical to the first capacitor type.

14. The power detection circuit of claim 12, further comprising a bias resistor having a first terminal coupled to the gate terminal of the input transistor and a second terminal configured to receive a bias voltage.

15. The power detection circuit of claim 12, further comprising:
a replica bias transistor having a gate terminal configured to receive a bias voltage;
a first load transistor coupled in series with the input transistor;
a second load transistor coupled in series with the replica bias transistor;
a first resistor coupled between gate and drain terminals of the first load transistor; and
a second resistor coupled between gate and drain terminals of the second load transistor.

16. The power detection circuit of claim 15, wherein the first and second resistors have adjustable resistances that are tuned to control a gain of the power detection circuit.

17. The power detection circuit of claim 11, wherein the attenuation circuit is configured to provide an attenuation factor that is tuned to adjust a linearity of the power detection circuit.

18. A power detector comprising:
an input transistor having a gate terminal configured to receive a radio-frequency signal;
a series capacitor of a given capacitor type coupled to the gate terminal of the input transistor; and
a shunt capacitor of the given capacitor type coupled to the gate terminal of the input transistor.

19. The power detector of claim 18, wherein the power detector has a linearity that is based on an attenuation factor provided by the series and shunt capacitors.

20. The power detector of claim 18, wherein the given capacitor type comprises one of: a metal-on-metal (MOM) capacitor, a metal-insulator-metal (MIM) capacitor, a metal-oxide-semiconductor (MOS) capacitor, a polysilicon-insulator-polysilicon (PIP) capacitor, and a trench capacitor.
